(19) United States
(12) Patent Application Publication
(10) Pub. No.: US 2013/0234731 A1
(43) Pub. Date: Sep. 12, 2013

(54) SYSTEMS AND METHODS FOR DETERMINING TRAPPED TRANSMISSION LINE CHARGE

(71) Applicant: Demetrios A. Tziouvaras, Vacaville, CA (US)

(72) Inventor: Demetrios A. Tziouvaras, Vacaville, CA (US)

(21) Appl. No.: 13/416,978

(22) Filed: Mar. 9, 2012

(51) Int. Cl. G01R 27/26

(52) U.S. Cl. 324/658

(57) ABSTRACT

The present disclosure provides systems and methods for calculating the trapped charge on a de-energized phase line connected to a capacitance-coupled voltage transformer (CCVT). According to various embodiments, the current through an auxiliary capacitive assembly may be measured and the current through a primary capacitive assembly may be measured or derived. According to various embodiments, the current sensors may both be positioned at zero-voltage points, eliminating the need for high-voltage insulated current sensors. An intelligent electronic device (IED) may determine the voltage with respect to time on the phase line using the measured and/or derived currents through the capacitive assemblies. If the phase line is de-energized, the IED may calculate the trapped charge on the de-energized phase line. The IED may use the calculated trapped charge to facilitate an optimized re-energization of the phase line, thereby reducing undesirable transients during re-energization.

### TECHNICAL FIELD

This disclosure relates to determining trapped charge on transmission lines. More particularly, this disclosure relates to systems and methods for determining trapped charge on uncompensated phase lines fitted with capacitance-coupled voltage transformers.

### BRIEF DESCRIPTION OF THE DRAWINGS

Non-limiting and non-exhaustive embodiments of the disclosure are described, including various embodiments of the disclosure, with reference to the figures, in which:

FIG. 1 illustrates a simplified circuit diagram of a phase line connected to a capacitance-coupled voltage transformer (CCVT).

FIG. 2 illustrates a circuit diagram of a phase line connected to a CCVT, including various tuning and protection circuits.

FIG. 3 illustrates an embodiment of a coupling-capacitor voltage divider that may be used to couple a phase line to a CCVT.

FIG. 4 illustrates an embodiment of a capacitance-bushing voltage divider that may be used to couple a phase line to a CCVT.

FIG. 5 illustrates an oscillographic comparison of an actual phase line voltage and a phase line voltage derived from measurements taken at the output of a CCVT.

FIG. 6 illustrates an oscillographic comparison of an actual phase line voltage and a phase line voltage derived from measurements taken at the output of a CCVT following a phase line de-energizing event.

FIG. 7 illustrates a method for determining the trapped charge on a phase line coupled to a CCVT.

FIG. 8 illustrates a method for determining the trapped charge on a phase line coupled to a CCVT, including adjusting capacitance parameters based on a measured temperature.

FIG. 9A illustrates a circuit diagram of one embodiment of a phase line coupled to a CCVT, including two current sensors useful for determining the voltage on the phase line.

FIG. 9B illustrates a circuit diagram of another embodiment of a phase line coupled to a CCVT, including two current sensors useful for determining the voltage on the phase line.

FIG. 9C illustrates a circuit diagram of another embodiment of a phase line coupled to a CCVT, including two current sensors useful for determining the voltage on the phase line.

FIG. 10 illustrates a circuit diagram of a phase line with a trapped charge coupled to a de-energized CCVT.

FIG. 11 illustrates an oscillographic comparison of the actual phase line voltage and the phase line voltage derived from CCVT current sensors.

In the following description, numerous specific details are provided for a thorough understanding of the various embodiments disclosed herein. The systems and methods disclosed herein can be practiced without one or more of the specific details, or with other methods, components, materials, etc. In addition, in some cases, well-known structures, materials, or operations may not be shown or described in detail in order to avoid obscuring aspects of the disclosure. Furthermore, the described features, structures, or characteristics may be combined in any suitable manner in one or more alternative embodiments.

### DETAILED DESCRIPTION

Intelligent electronic devices (IEDs) may be used for monitoring, protecting, and/or controlling industrial and utility equipment, such as in electric power delivery systems. IEDs may be configured to obtain measurement information from current sensors and/or voltage sensors, such as current transformers (CTs) and/or voltage potential transformers (PTs). IEDs may be configured to obtain measurement information from a variety of other sources, such as optical current transducers, Rogowski coils, light sensors, relays, temperature sensors, and similar devices, as well as from measurements, signals, or data provided by other IEDs. IEDs within a power system may be configured to perform metering, control, switching, and protection functions based on measured data. In some embodiments, an IED may be configured to monitor, protect, and/or control the de-energization and/or re-energization of power distribution lines.

Power distribution systems may include various transmission and distribution lines. In many instances power is transmitted as three-phase power, with each phase of power carried over a single phase line. In other embodiments, any number of phase lines may be used to transmit power from one point to another. Phase lines may be switched on and off (de-energized) with relative frequency in some configurations, and rarely de-energized in other situations. For example, a critical transmission line may only be disconnected as the result of a breaker tripping under fault conditions or during scheduled maintenance. When a phase line is initially connected to a power source, the phase line is energized with an initial voltage potential. In a three-phase power system, the phase line may be energized with an alternating current at approximately 60 Hz.

When the phase line is disconnected from the power source (e.g., a breaker trips), the phase line looses the 60 Hz voltage signal. Excess charge on the phase line dissipates quickly if the phase line is terminated with a magnetic voltage transformer or other component that allows for DC voltage discharge. However, if the phase line terminates with a capacitive coupled voltage transformer (CCVT), then a DC voltage may remain on the de-energized phase line as “trapped charge.”

Re-energization of a phase line with a trapped charge can result in severe switching transients. For example, reclosing a transmission line when trapped charge is present on one of the three phase lines in a three-phase power system may result in severe transient overvoltages, and/or other undesirable conditions. A significant factor in the design of extra-high voltage (EHV) lines is the expected level of switching transients. Accordingly, the ability to limit switching transients to lower levels with controlled closing of de-energized phase lines could provide significant benefits. The benefits may include a reduction in the cost of phase line design and a reduction in temporary overvoltages (TOVs), which may task surge arresters and expose equipment to overvoltages exceeding their voltage ratings.

In some embodiments, pre-insertion resistors, surge arresters, and current-limiting reactors may be employed to reduce the magnitude and impact of switching transients. In other embodiments, controlled re-energization can, in many cases, provide an effective means of mitigating transients due to reclosing phase lines with trapped charge. In order to perform an optimized re-energization of a phase line, it is necessary to know the magnitude and polarity of the trapped charge on the phase line. The phase line may be optimally re-energized by matching the prospective re-energizing voltage with the trapped charge. In some embodiments, resistive dividers and/or inductive voltage transformers (IVTs) may be used to accurately determine the voltage on a high-voltage phase line.

Due to cost, size, and other considerations, CCVTs are commonly employed in high-voltage systems. However, the secondary output of CCVTs becomes distorted and decays rapidly to zero following the loss of a 60 HZ voltage signal. Accordingly, it is difficult or impossible to determine the trapped charge on a de-energized phase line using the output voltage of a CCVT. Specifically, using the output voltage (the secondary windings) of a step-down transformer in a CCVT configuration is unsuitable for calculating the trapped charge on a phase line on the side of the primary windings of the transformer. This is due, at least in part, to the fact that the CCVT acts as a band-pass filter suppressing low frequency components of the input signal.

According to various embodiments of the present disclosure, a transformer is configured in a CCVT configuration using a coupling-capacitor voltage divider or a capacitance-bushing voltage divider. In various configurations, the primary winding of the transformer “taps” a point in between a primary capacitive assembly and an auxiliary capacitive assembly. The primary capacitive assembly may couple the primary winding of the transformer to a high voltage phase line, and the auxiliary capacitive assembly may couple the same side of the primary winding to a neutral point (or other reference point).

An IED may be used to measure the current through the primary capacitive assembly using a first current sensor, such as a CT or Rogowski coil. The IED may also measure the current through the auxiliary capacitive assembly using a second current sensor. In some embodiments, the current through the primary capacitive assembly and the auxiliary capacitive assembly may be directly measured. In some embodiments, the current sensors may be positioned at neutral, ground, or low voltage locations in order to reduce the difficulty in obtaining accurate current measurements.

For example, the current through the auxiliary capacitive assembly may be measured via a current sensor positioned between the auxiliary capacitive assembly and ground. The current through the primary capacitive assembly may be deduced using the current through the auxiliary capacitive assembly and a current measured between the grounded side of the primary winding and ground. Accordingly, the current through the primary and auxiliary capacitive assemblies may be determined using current sensors positioned at zero-voltage points.

The IED may determine a de-energization time corresponding to the instant the phase line is de-energized. The IED may calculate the voltage on the phase line using the current through the primary capacitive assembly, the current through the auxiliary capacitive assembly, and the capacitances of the primary and auxiliary capacitive assemblies. The IED may use the calculated voltage to determine a trapped charge on a transmission line at the de-energization time when the phase line was de-energized.

During re-energization, the IED may communicate with one or more additional IEDs, breakers, relays, and/or other power system components in order to ensure that the re-energizing voltage applied to the phase line is matched with the trapped charge on the phase line. As previously described, by matching the re-energizing voltage with the trapped charge, unwanted transients can be minimized or eliminated.

The phrases “connected to” and “in communication with” refer to any form of interaction between two or more components, including mechanical, electrical, magnetic, and electromagnetic interaction. Two components may be connected to each other, even though they are not in direct contact with each other, and even though there may be intermediary devices between the two components.

As used herein, the term IED may refer to any microprocessor-based device that monitors, controls, automates, and/or protects monitored equipment within a system. Such devices may include, for example, remote terminal units, differential relays, distance relays, directional relays, feeder relays, overcurrent relays, voltage regulator controls, voltage relays, breaker failure relays, generator relays, motor relays, automation controllers, bay controllers, meters, recloser controls, communications processors, computing platforms, programmable logic controllers (PLCs), programmable automation controllers, input and output modules, motor drives, and the like. IEDs may be connected to a network, and communication on the network may be facilitated by networking devices, including, but not limited to, multiplexers, routers, hubs, gateways, firewalls, and switches. Furthermore, networking and communication devices may be incorporated in an IED or be in communication with an IED. The term IED may be used interchangeably to describe an individual IED or a system comprising multiple IEDs.

Aspects of certain embodiments described herein may be implemented as software modules or components. As used herein, a software module or component may include any type of computer instruction or computer executable code located within or on a computer-readable storage medium. A software module may, for instance, comprise one or more physical or logical blocks of computer instructions, which may be organized as a routine, program, object, component, data structure, etc., that performs one or more tasks or implements particular abstract data types.

The embodiments of the disclosure will be best understood by reference to the drawings, wherein like parts are designated by like numerals throughout. The components of the disclosed embodiments, as generally described and illustrated in the figures herein, could be arranged and designed in a wide variety of different configurations. Thus, the following detailed description of the embodiments of the systems and methods of the disclosure is not intended to limit the scope of the disclosure, as claimed, but is merely representative of possible embodiments. In other instances, well-known structures, materials, or operations are not shown or described in detail to avoid obscuring aspects of this disclosure. In addition, the steps of a method do not necessarily need to be executed in any specific order, or even sequentially, nor need the steps be executed only once, unless otherwise specified.

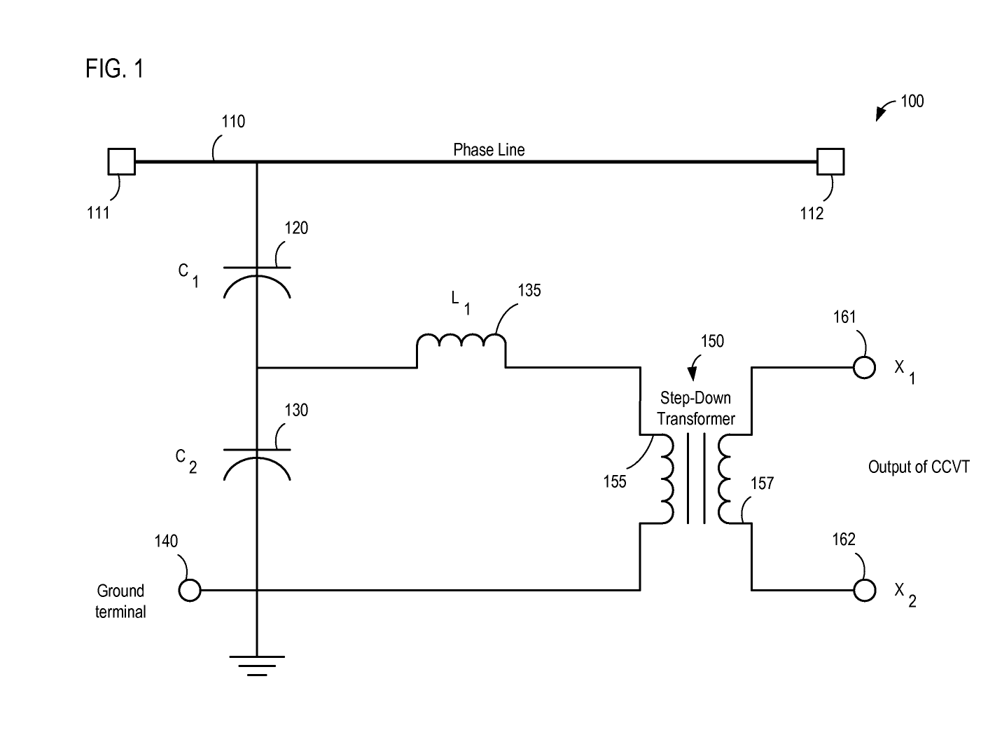

FIG. 1 illustrates a simplified circuit diagram of a phase line 110 connected to a capacitance coupled voltage transformer (CCVT) 100. Phase line 110 may be terminated on either end with a breaker 111 and 112. According to some embodiments, breaker 111 may connect an AC power source to phase line 110. Breaker 112 may connect phase line 110 to additional components and/or transmission lines. Alternatively, breaker 112 may be omitted and phase line 110 may terminate with CCVT 100.

As illustrated, simplified CCVT 100 includes a transformer 150 including a primary winding 155 and a secondary (output) winding 157. The output voltage of CCVT 100 is measured across terminals X1 161 and X2 162 on secondary winding 157. In various embodiments, transformer 150 may be a step-down transformer (i.e. the voltage potential across primary winding 155 is higher than that across the secondary winding 157). As illustrated, transformer 150 is considered a CCVT because of primary capacitive assembly (C1) 120 and auxiliary capacitive assembly (C2) 130. Additionally, an inductor (L1) 135 may be configured to tune CCVT 100 in order to improve accuracy.

Primary winding 155 may be said to “tap” the junction of C1 120 and C2 130. C1 120 may couple primary winding 155 to phase line 110. C2 130 may couple the high-voltage side of primary winding 155 to ground 140. Ground 140 may be a physical ground, a neutral point, a neutral phase line, or another phase line in a three-phase power system. CCVT 100 may be used to step down high-voltage phase line 110 to a lower voltage across X1 161 and X2 162. For example, phase line 110 may have a potential of 230 KV and the outputs X1 161 and X2 162 of CCVT 100 may have a potential of 115 V. CCVT 100, including capacitive assemblies C1 120 and C2 130, may be smaller and/or less costly to manufacture than an equivalent inductive transformer.

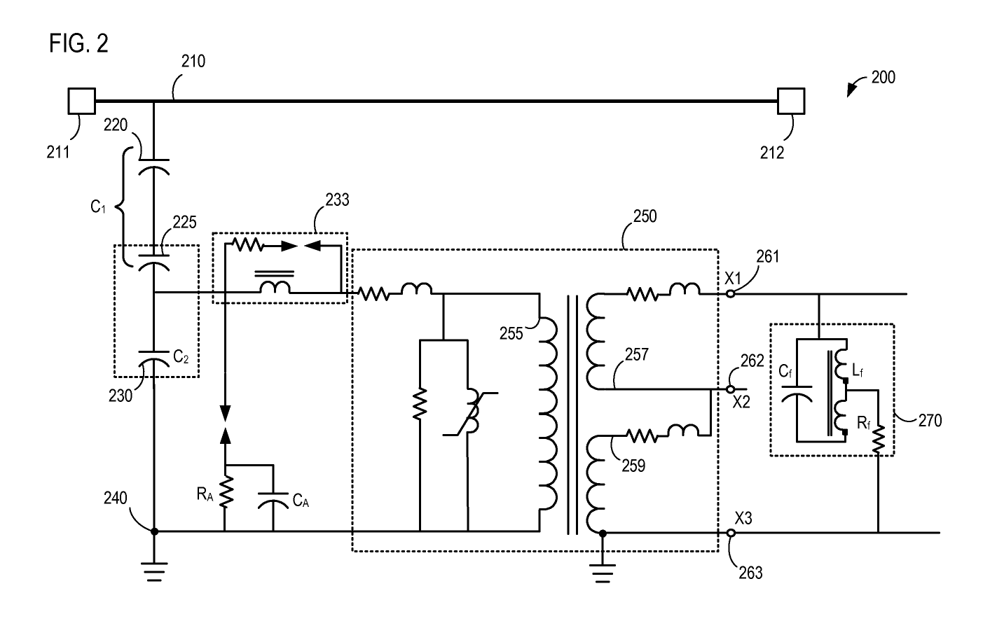

As previously stated, FIG. 1 illustrates a simplified diagram of a CCVT 100. The present systems and methods are applicable to both passive CCVTs and active CCVTs. FIG. 2 illustrates a circuit diagram of a phase line 210 connected to an active single-phase CCVT 200, including various tuning and protection circuits. Phase line 210 may be selectively disconnected from an AC power source via breaker 211. Breaker 212 may connect phase line 210 to additional components or phase lines in a power distribution system. CCVT 200 includes primary capacitive assembly (comprising capacitor 220 and capacitor 225) and auxiliary capacitive assembly 230. A compensating reactor 233 may include inductive, capacitive, and/or resistive elements. A ferroresonant suppression circuit (FSC) 270 may be connected to output terminals X1 261 and X3 263 across secondary windings 257 and 259. FSC 270 may reduce or eliminate ferroresonant conditions within the CCVT 200 that might otherwise cause damaging overvoltages and/or overcurrents.

Primary capacitive assembly 220 and 225 may couple the high-voltage side of primary winding 255 to high-voltage phase line 210. Auxiliary capacitive assembly 230 may couple the high voltage side of primary winding 255 to a neutral point 240, such as ground. Accordingly, primary capacitive assembly 220 and 225 and auxiliary capacitive assembly 230 may be part of a coupling-capacitor voltage divider or a capacitance-bushing voltage divider with the high-voltage side of the primary winding coupled to the “tap” of such devices. Transformer 250 may be a step-down transformer and include one or more secondary windings 257 and 259. Various desired output voltages may be achieved using any number of secondary windings and associated terminals, such as terminals X1 261, X2 262, and X3 263.

The interaction of the various capacitive and reactive elements in CCVT 200 results in transient errors in the secondary voltage output during switching and faults. As previously described, the poor transient response of CCVTs makes it difficult or impossible to accurately determine the trapped charge on a phase line after it has been disconnected from the AC power source via breaker 211 and/or 212. For example, the voltage measured at outputs X1 261 and X3 263 is unsuitable to determine a DC charge on phase line 210 once it is de-energized.

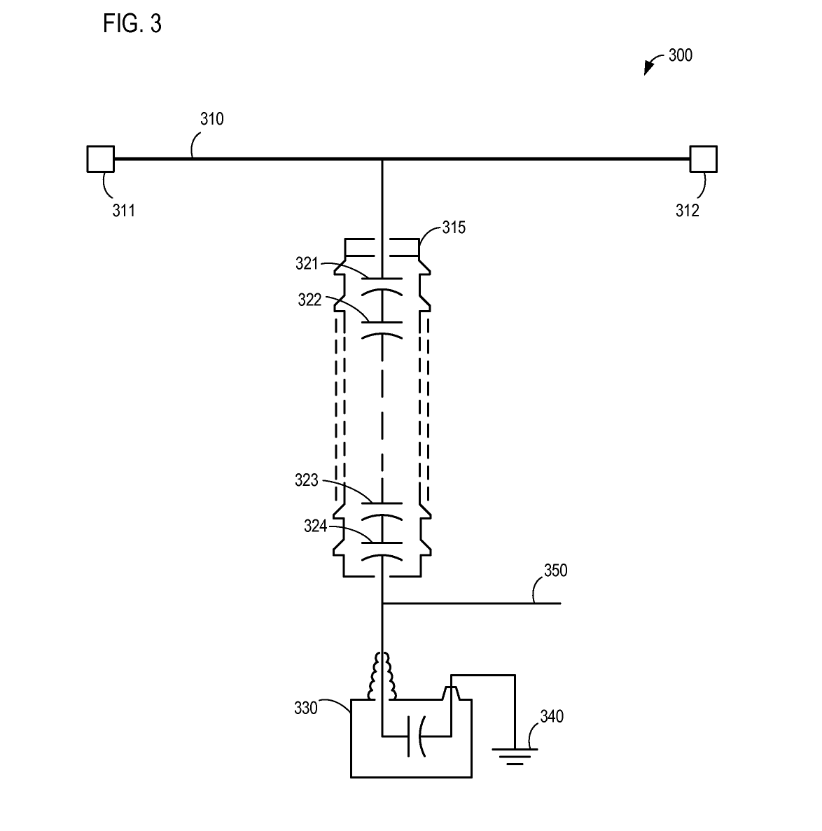

FIG. 3 illustrates an embodiment of a coupling-capacitor voltage divider 300 that may be used in conjunction with a transformer to form a CCVT. A primary capacitive assembly, comprising capacitive elements 321, 322, 323, and 324 may couple a high-voltage phase line 310 to a “tap” 350. Since the voltage on both sides of capacitive elements 321, 322, 323, and 324 (forming the primary capacitive assembly) is relatively high, primary capacitive elements 321, 322, 323, and 324 may be housed within an insulating bushing 315. “Tap” 350 may be coupled to a neutral point 340 via an auxiliary capacitive assembly 330. Accordingly, high-voltage phase line 310 may be coupled to neutral via primary capacitive elements 321, 322, 323, and 324 and auxiliary capacitive assembly 330. The primary winding of a transformer may be connected to “tap” 350 positioned between primary capacitive elements 321, 322, 323, and 324 and auxiliary capacitive assembly 330.

Capacitive elements 321, 322, 323, and 324 allow a 60 Hz AC power signal to flow, but may not allow DC charge to flow. Accordingly, if phase line 310 is disconnected from an AC power source, via breakers 311 and/or 312, a DC trapped charge may remain on phase line 310. Phase line 310 may have high-voltage trapped charge, while tap 350 is at zero voltage.

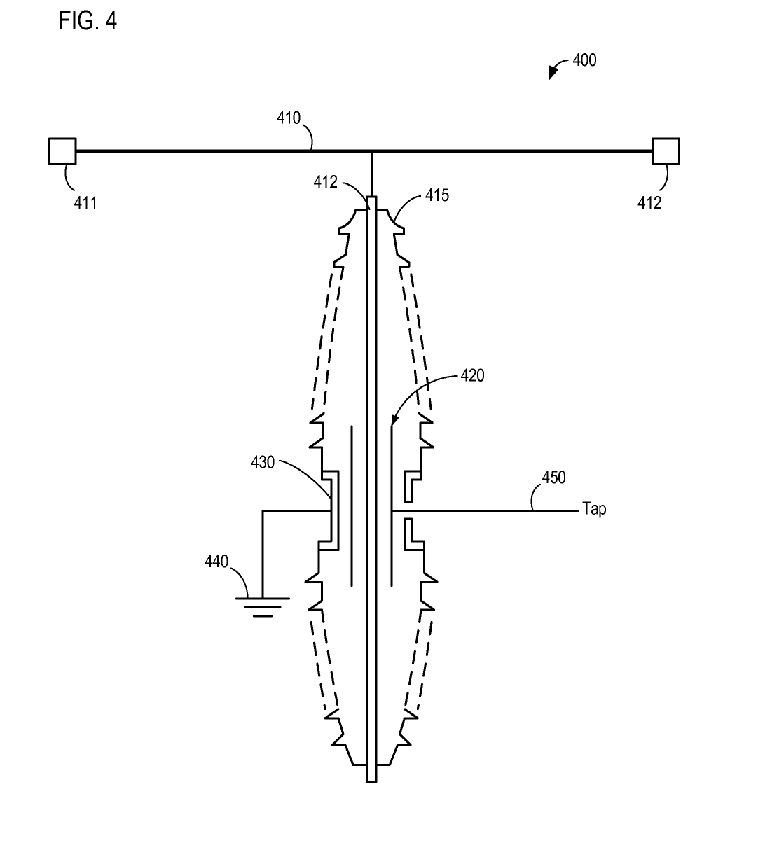

FIG. 4 illustrates an embodiment of a capacitance-bushing voltage divider 400 that may be used in conjunction with a bushing potential device. Capacitance-bushing voltage divider 400 may include a center conductor 412 attached to a high-voltage phase line 410. An insulating bushing 415 may surround center conductor 412. Insulating bushing 415 may include one or more layers of capacitive and dielectric materials. A first capacitive layer 420 may be used to couple a tap 450 to high-voltage phase line 410. Accordingly, center conductor 412 and first capacitive layer 420 may form a primary capacitive assembly that couples tap 450 to phase line 410. A second capacitive layer 430 in conjunction with first capacitive layer 420 and center conductor 412 may form an auxiliary capacitive assembly coupling tap 450 and phase line 410 to neutral point 440. The primary winding of a transformer may be connected to tap 450 in order to form a bushing potential device. Accordingly, a CCVT, as used herein, may comprise a step-down transformer connected to a phase line via a bushing capacitance-bushing voltage divider 400, such that first capacitive layer 420 serves as a primary capacitive assembly and second capacitive layer 430 serves as an auxiliary capacitive assembly.

Again, if breakers 411 and/or 412 are opened, phase line 410 may be disconnected from an AC power signal. Remaining AC voltages would quickly dissipate on phase line 410, but a DC trapped charge would remain on phase line 410. The DC trapped charge would remain on phase line 410 since capacitive layers 420 and 430 may prevent the DC charge from dissipating.

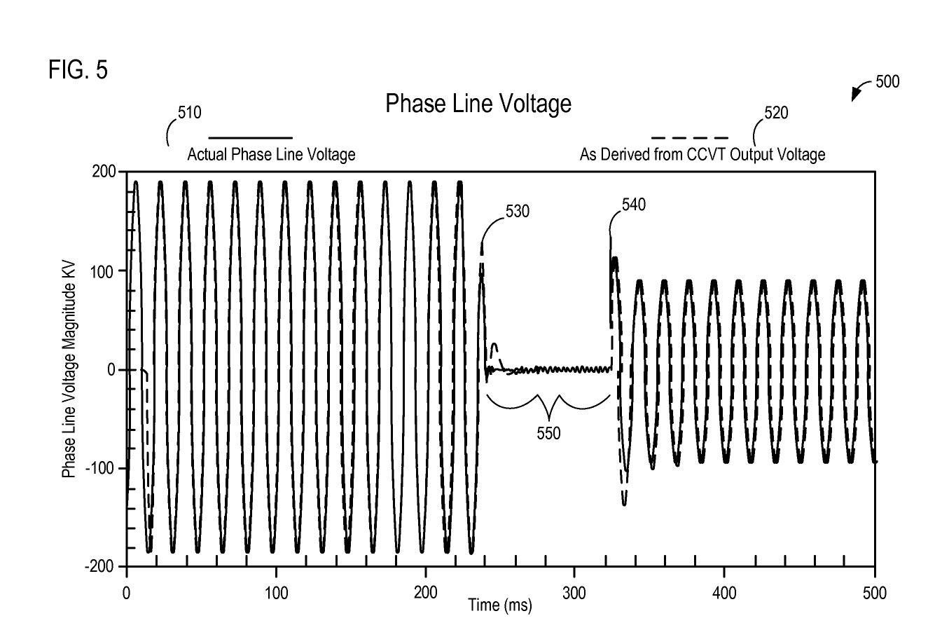

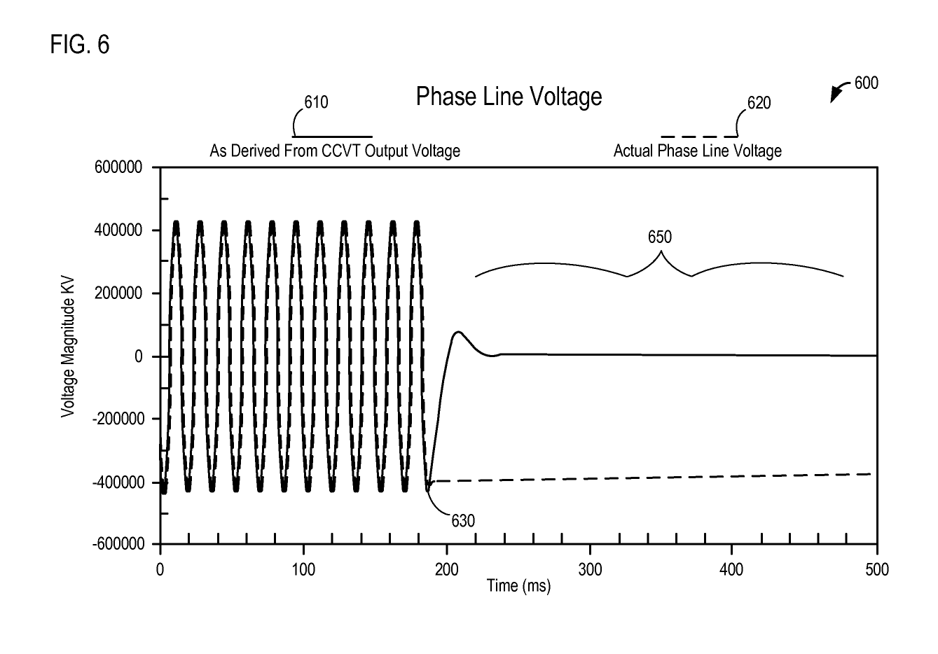

As described above, while CCVTs may be smaller and/or cheaper than an equivalent inductive transformer, the poor transient response of CCVTs makes it difficult or impossible to accurately determine the trapped charge on a de-energized phase line using the output of the CCVT. Accordingly, the voltage measured at the output of the CCVT is unsuitable to determine the trapped charge on a de-energized phase line. FIGS. 5 and 6 illustrate various oscillographic reports that demonstrate the limitations of CCVTs. Specifically, that while the output voltage of a CCVT corresponds to the actual voltage across the primary winding of a transformer, the output voltage of the CCVT cannot be used to accurately determine trapped charge on a de-energized phase line. The oscillographic reports of FIGS. 5 and 6 correspond to a CCVT, such as CCVT 200 illustrated in FIG. 2, which includes primary and auxiliary capacitive assemblies, such as those shown in FIGS. 3 and 4.

FIG. 5 illustrates an oscillographic comparison 500 of the actual phase line voltage 510 and the phase line voltage derived using the voltage measured at the output of a CCVT (derived phase line voltage 520). At a time zero (along the X-axis) the actual phase line voltage 510 alternates between approximately −200 KV and 200 KV (along the Y-axis). At approximately 240 ms, at 530, the phase line is de-energized and the actual phase line voltage 510 drops to approximately zero for duration 550. At approximately 320 ms, at 540, the phase line is re-energized and the actual phase line voltage 510 alternates between approximately −100 KV and 100 KV.

The transformer may be a step-down transformer having a known winding ratio. Accordingly, the phase line voltage may be derived using the voltage measured at output of the CCVT. As illustrated in FIG. 5, the derived phase line voltage 520 based on the measured voltage at the output of the CCVT is relatively accurate, though imperfect due to the poor transient response of CCVTs.

FIG. 6 illustrates an oscillographic comparison 600 of the actual phase line voltage 620 and the phase line voltage derived using the output of the CCVT (derived phase line voltage 610). As illustrated, when the phase line is de-energized, at 630, a DC trapped charge of about −400,000 KV remains on the phase line, at 650. The derived phase line voltage 610 erroneously indicates that the phase line has a zero voltage, at 650, during de-energization. Accordingly, FIGS. 5 and 6 illustrate that while the voltage measured at the output of a CCVT corresponds to the actual phase line voltage (see FIG. 5), a DC trapped charge on the phase line is not calculable using the voltage measured at the output of a CCVT.

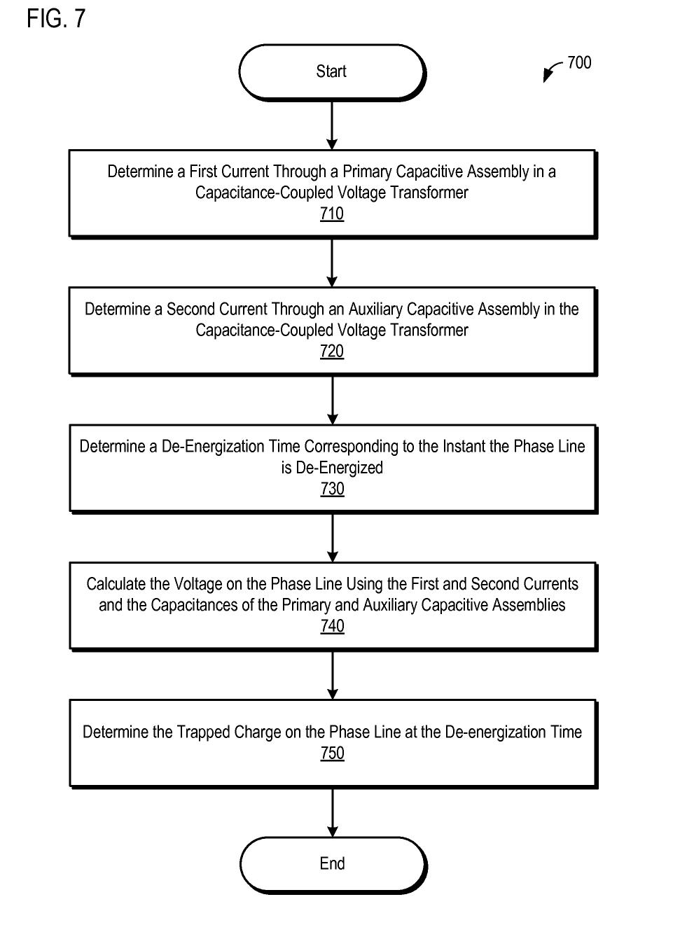

FIG. 7 illustrates a method 700 for accurately determining the trapped charge on a phase line connected to a CCVT. The method 700 could be repeated for each phase of a multi-phase power system utilizing independent transformers for each phase. Similarly, the method 700 could be adapted to accommodate a multi-phase power system in which one or more phase lines are connected to one or more transformer cores.

With regards to one phase in a three-phase power system, an IED may determine a first current through a primary capacitive assembly in a CCVT, at 710. The IED may determine a second current through an auxiliary capacitive assembly in the CCVT, at 720. The IED may then determine a de-energization time corresponding to the instant the phase line is de-energized, at 730. The IED may calculate the voltage on the phase line using the first and second currents, the capacitance (or associated reactance) of the primary capacitive assembly, and the capacitance (or associated reactance) of the auxiliary capacitive assembly, at 740. The IED may determine the trapped charge on the phase line at the de-energization time, at 750.

According to various embodiments, a local IED may utilize distributed or cloud computing developments to reduce the data storage or processing demands. For example, the local IED may receive signals from current sensors associated with the primary and auxiliary capacitive assemblies and transmit the current signals to a remote IED configured to store and/or process the data. The local IED (or other IED configured to monitor, protect, and/or control aspects of the power system associated with the phase line) may then receive instruction from the remote IED with regards to breaker switching, or other related events, in order to ensure that a phase line is optimally re-energized.

In some embodiments, the current through the primary capacitive assembly and the auxiliary capacitive assembly may be directly measured. In some embodiments, current sensors may be positioned at neutral, ground, or low voltage locations in order to reduce the difficulty in obtaining accurate current measurements. For example, the current through the auxiliary capacitive assembly may be measured via a current sensor positioned between the auxiliary capacitive assembly and ground. The current through the primary capacitive assembly may be deduced using the current through the auxiliary capacitive assembly and a current measured between the grounded side of the primary winding and ground. Accordingly, the current through the primary and auxiliary capacitive assemblies may be determined using current sensors positioned at zero-voltage points.

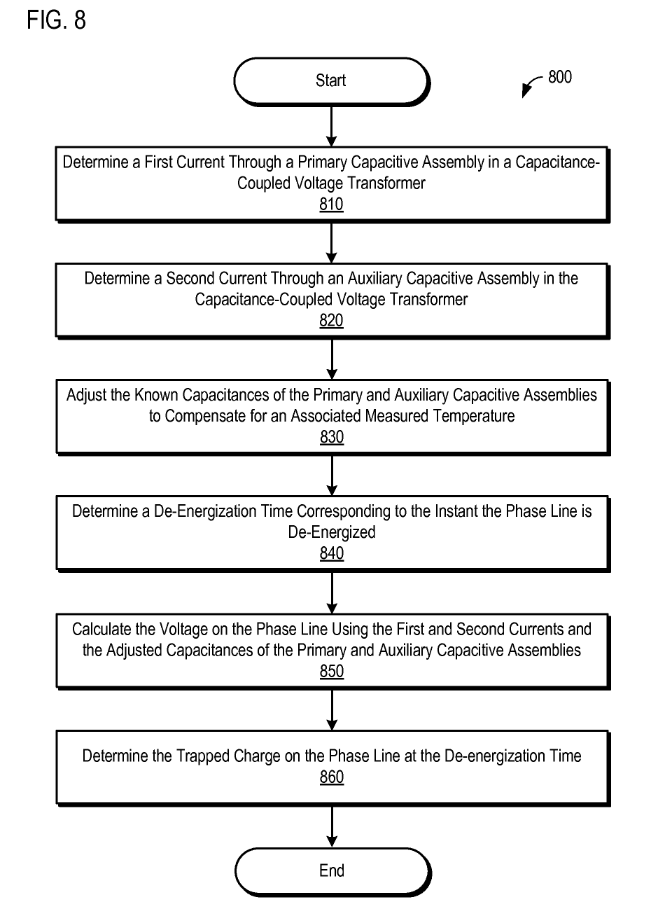

FIG. 8 illustrates a related method 800 for accurately determining the trapped charge on a phase line connected to a CCVT. The methods of FIGS. 7 and 8 are described as being performed by an IED, however, various machines, apparatuses, and/or persons could alternatively perform method 800. Moreover, the systems and methods described herein could be implemented as machine instructions executable by a processor in an IED. Initially, an IED determines the current through the primary capacitive assembly in the CCVT, at 810. The IED determines the current through the auxiliary capacitive assembly in the CCVT, at 820. For purposes of subsequent calculations, the known capacitances of the primary and auxiliary capacitive assemblies may be adjusted to compensate for an associated measured temperature, at 830. For example, one or more temperature sensors may be used to measure the ambient temperature near a capacitive component in the primary or auxiliary capacitive assemblies. Alternatively, one or more temperature sensors may be used to directly measure the temperature of the primary and/or auxiliary capacitive assemblies. Adjusting the capacitance value of the primary and/or auxiliary capacitive assemblies based on the temperature may provide increased accuracy for subsequent calculations.

The IED may then determine a de-energization time corresponding to the instant the phase line is de-energized, at 840. The IED calculates the voltage on the phase line using the first and second currents and the adjusted capacitances of the primary and auxiliary capacitive assemblies, at 850. The IED may then determine the trapped charge on the phase line at the de-energization time, at 860.

Again, the current through the primary capacitive assembly and the auxiliary capacitive assembly may be directly measured. Alternatively, current sensors may be positioned at neutral, ground, or low voltage locations in order to reduce the difficulty in obtaining accurate current measurements. Accordingly, the current through the auxiliary capacitive assembly may be measured via a current sensor positioned between the auxiliary capacitive assembly and ground. The current through the primary capacitive assembly may be deduced using the current through the auxiliary capacitive assembly and a current measured between the grounded side of the primary winding and ground.

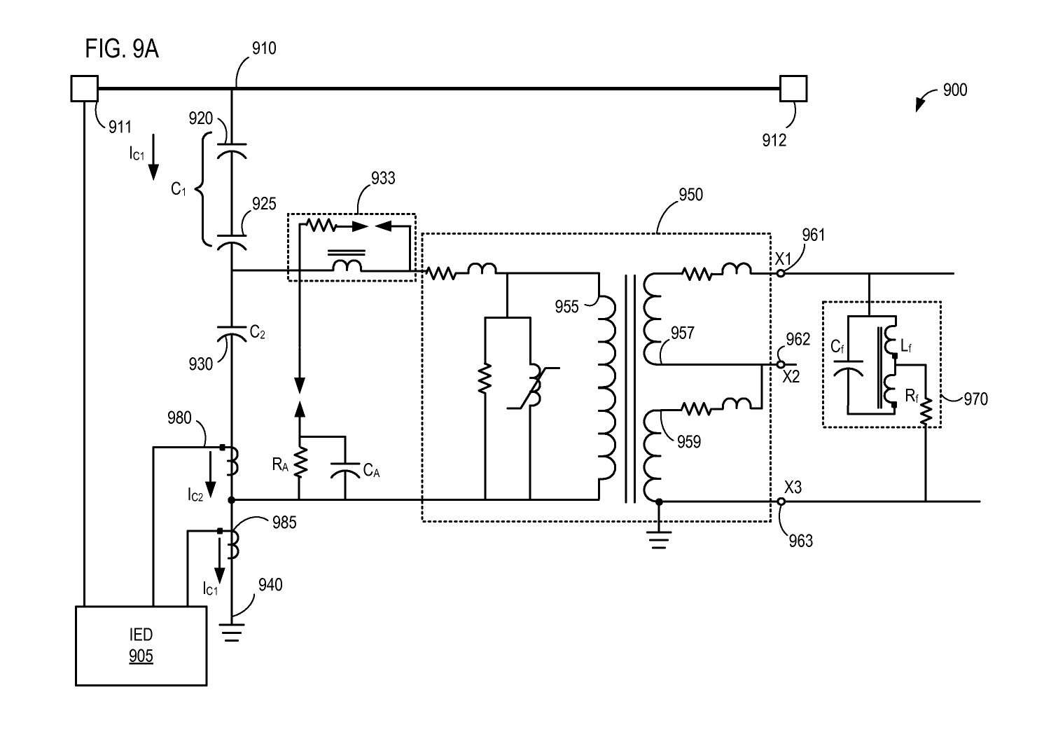

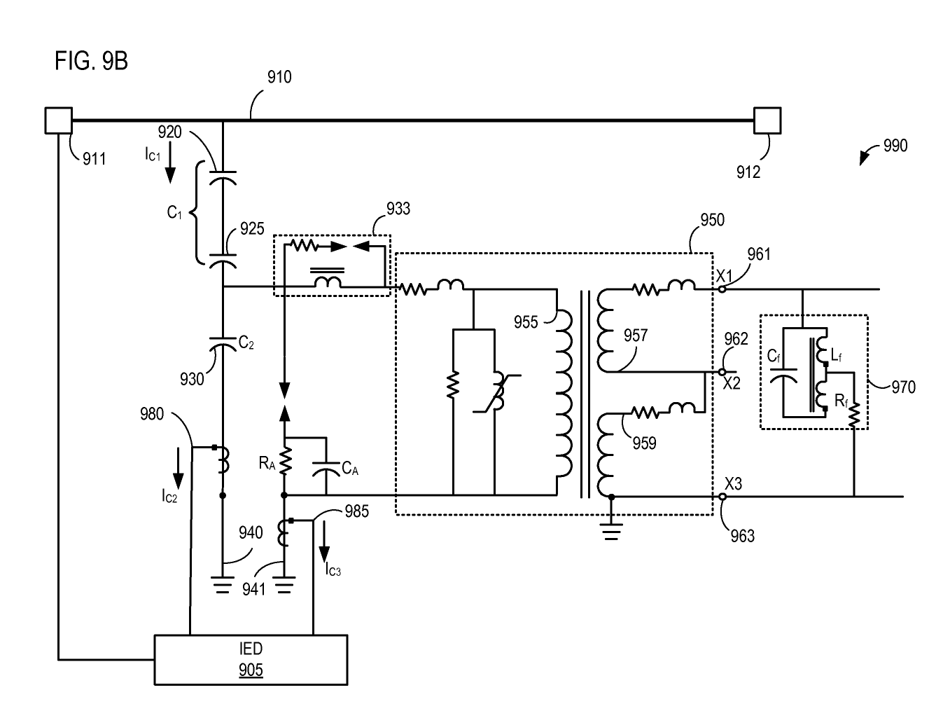

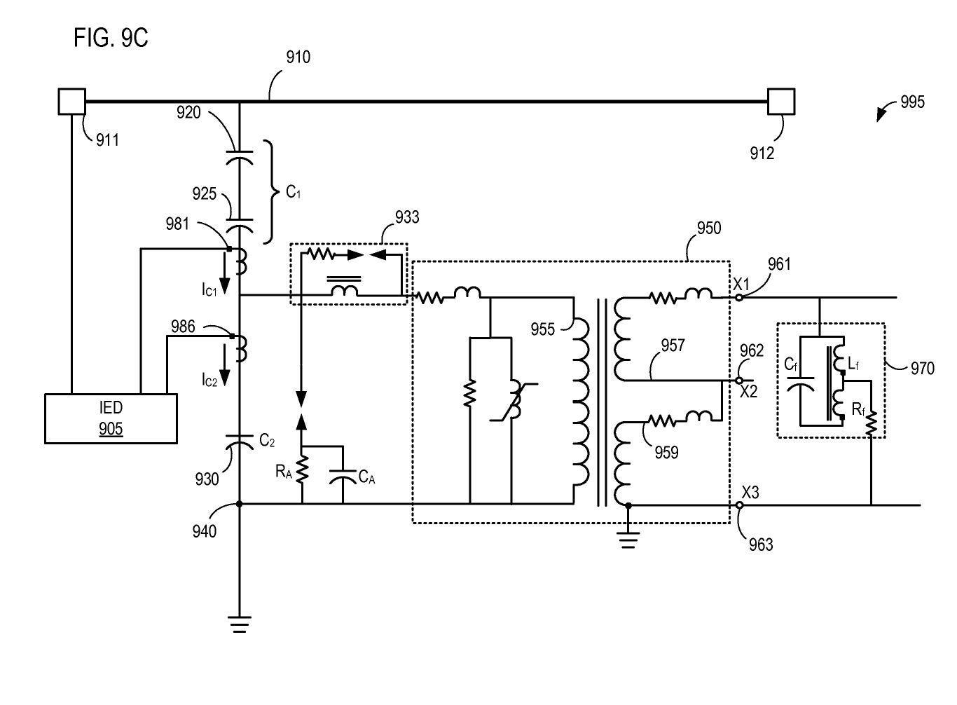

FIG. 9A illustrates a circuit diagram of one embodiment of a CCVT 900, including two current sensors 980 and 985 useful for determining the trapped charge on phase line 910. The illustrated CCVT configuration is similar to that described in conjunction with FIG. 2, and may utilize a coupling-capacitor voltage divider or a capacitance-bushing voltage divider, as illustrated in FIGS. 3 and 4 respectively. FIG. 9A illustrates a circuit diagram including the main components of an active single-phase CCVT 900, including various tuning and protection circuits. CCVT 900 includes primary capacitive assembly (comprising capacitive elements 920 and 925) and auxiliary capacitive assembly 930. A compensating reactor 933 may include inductive, capacitive, and/or resistive elements. A ferroresonant suppression circuit (FSC) 970 may be connected to output terminals X1 961 and X3 963 across secondary windings 957 and 959. FSC 970 may reduce or eliminate ferroresonant conditions within the CCVT that might otherwise cause damaging overvoltages and/or overcurrents.

Primary capacitive assembly 920 and 925 may couple the high-voltage side of primary winding 955 to high-voltage phase line 910. Auxiliary capacitive assembly 930 may couple the high voltage side of primary winding 955 to a neutral point 940, such as ground. Transformer 950 may be a step-down transformer and include one or more secondary winding 957 and 959. Various desired output voltages may be achieved using any number of secondary windings and associated terminals, such as terminals X1 961, X2 962, and X3 963.

The interaction of the various capacitive and reactive elements in CCVT 900 results in transient errors in the secondary voltage output during switching and faults. As previously described, the poor transient response of CCVTs makes it difficult or impossible to accurately determine the trapped charge on phase line 910 when breaker 911 and/or breaker 912 are opened. For example, the voltage measured at outputs X1 961 and X3 963 is unsuitable to determine the DC trapped charge on phase line 910 because capacitive element 920 and/or capacitive element 925 filter DC voltages.

IED 905 may be in communication with current sensors 980 and 985 configured to measure the current I_{C2} through auxiliary capacitive assembly 930 and the current I_{C1} through primary capacitive assembly 920 and 925, respectively. Measuring currents I_{C1} and I_{C2} and having knowledge of the capacitive values of primary capacitive assembly 920 and 925 and auxiliary capacitive assembly 930 allows for the reconstruction of the voltage of phase line 910. Knowing the voltage of phase line 910 and detecting a de-energization time corresponding to when breaker 911 is opened (disconnecting phase line 910 from an AC power source), allows for the calculation of the trapped charge on phase line 910. As previously described, knowledge of the trapped charge on a phase line can be used to considerably reduce undesirable transients during the subsequent re-energization of the phase line.

To calculate the voltage of phase line 910, the following equation can be used:

V=jI_{C1}X_{C1}+jI_{C2}X_{C2} Equation 1

In equation 1 above, V is the voltage of phase line 910, I_{C1} is the current in primary capacitive assembly 920 and 925, I_{C2} is the current in auxiliary capacitive assembly 930, X_{C1} is the capacitive reactance of primary capacitive assembly 920 and 925, and X_{C2} is the capacitive reactance of auxiliary capacitive assembly 930. In the time domain, equation 1 can be expressed as:

$$v ( t ) = \frac{1}{{C}_{1}} \int {i}_{C 1} d t + \frac{1}{{C}_{2}} \int {i}_{C 2} d t \qquad Equation 2$$

In equation 2 above, V(t) is the instantaneous voltage of phase line 910, I_{C1} is the instantaneous current in primary capacitive assembly 920 and 925, I_{C2} is the instantaneous current in auxiliary capacitive assembly 930, C₁ is the capacitance of primary capacitive assembly 920 and 925, and C₂ is the capacitance of auxiliary capacitive assembly 930. Using equation 2 above, the DC trapped charge may be calculated by determining the voltage at the instant the phase line underwent a de-energization event (i.e. the de-energization time).

FIG. 9A illustrates one possible configuration of a CCVT 900 and one possible location for positioning current sensors 980 and 985. It should be apparent to one of skill in the art that two or more current sensors may be placed at varying locations within the circuit diagram of FIG. 9A and still allow for the calculation of the currents through the primary and auxiliary capacitive assemblies. Specifically, using the electrical principles described in Kirchhoff's first and second laws, currents sensors 980 and 985 may be placed in a wide variety of locations. Kirchhoff's laws may be adapted to account for Faraday's law of induction related to the inductors associated with CCVT 900 by associating a potential drop or electromotive force with each inductor in the circuit (e.g., primary winding 955).

FIG. 9B illustrates a circuit diagram of another embodiment of a CCVT 990, in which a neutral connection 941 of primary winding 955 of transformer 950 is not shared with neutral connection 940 of auxiliary capacitive assembly 930. The other components are similar to those described in conjunction with FIG. 9A having similar reference numbers. According to the embodiment illustrated in FIG. 9B, IED 905 may receive current measurements I_{C2} and I_{C3}. I_{C2} corresponds to the current through the auxiliary capacitive assembly. IED 905 may derive the current, I_{C1}, through primary capacitive assembly 920 and 925 using I_{C2} and I_{C3}.

Measuring or deriving currents I_{C1} and I_{C2} and having knowledge of the capacitive values of primary capacitive assembly 920 and 925 and auxiliary capacitive assembly 930 allows for the reconstruction of the voltage of phase line 910 using equations 1 and/or 2 above. The instantaneous voltage at the de-energization time may be calculated in order to determine the trapped charge on phase line 910 following a de-energization event. As previously described, knowledge of the trapped charge on a phase line can be used to considerably reduce undesirable transients during the subsequent re-energization of the phase line.

FIG. 9C illustrates a circuit diagram of another embodiment of a CCVT 995, including two high-voltage current sensors 981 and 986 configured to directly measure the current through primary capacitive assembly 920 and 925 and auxiliary capacitive assembly 930. The other components of CCVT 995 are similar to those described in conjunction with FIG. 9A having similar reference numbers. IED 905 may receive the current measurement made by high-voltage current sensors 981 and 986. The IED 905 may then reconstruct the voltage of phase line 910 using equations 1 and/or 2 above. IED 905 may then determine the instantaneous voltage at the de-energization time in order to calculate the trapped charge on phase line 910. As previously described, knowledge of the trapped charge on a phase line can be used to considerably reduce undesirable transients during the subsequent re-energization of the phase line.

A primary advantage of the embodiments illustrated in FIGS. 9A and 9B is that current sensors 980 and 985 are located at a zero-voltage location in the respective CCVTs 900 and 990. Accordingly, the cost and size of current sensors 980 and 985 may be significantly lower than high-voltage current sensors 981 and 986. However, any of the configurations shown in FIGS. 9A-9C may be used in conjunction with presently described systems and methods. Additionally, current sensors may be positioned in any of a wide variety of locations in a CCVT, so long as they provide sufficient information for an IED to calculate or derive the current through each of the primary and auxiliary capacitive assemblies.

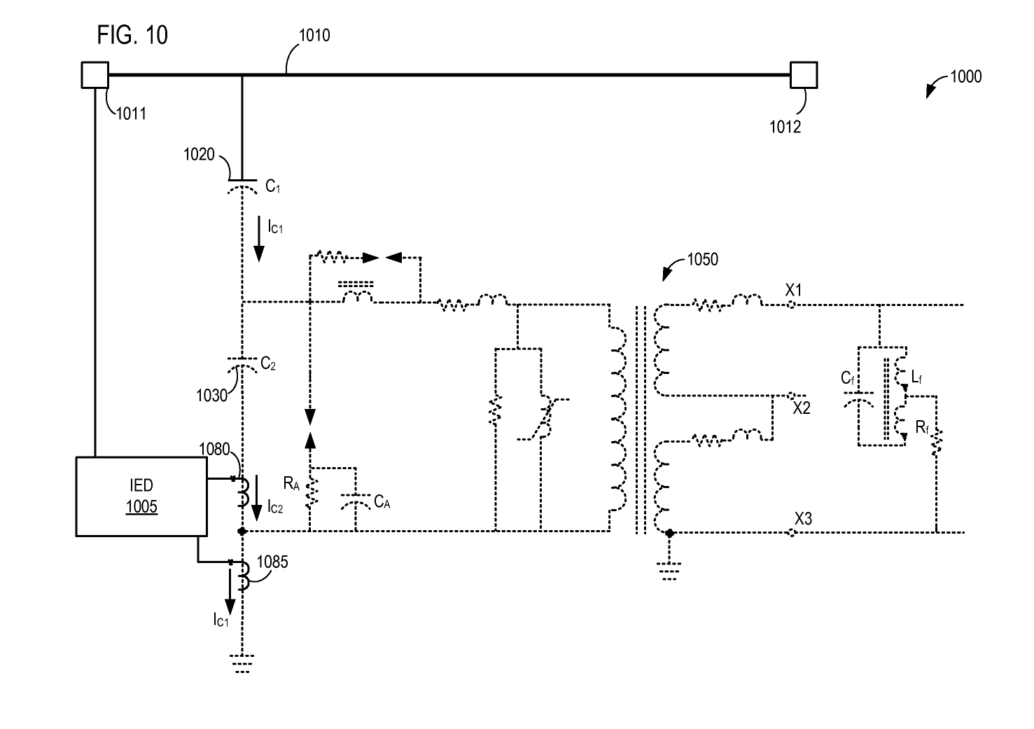

FIG. 10 illustrates a circuit diagram of a phase line 1010 with a trapped charge coupled to a de-energized CCVT 1000. As illustrated, phase line 1010 is coupled to transformer 1050 via a primary capacitive assembly 1020, and to ground via an additional auxiliary capacitive assembly 1030. Transformer 1050 is illustrated as de-energized completely as dashed lines, while phase line 1010 is shown has having a DC trapped charge that cannot be discharged because of primary capacitive assembly 1020 of CCVT 1000. IED 1005 may have used current measurements obtained via current sensors 1080 and 1085 to reconstruct the voltage of phase line 1010. By detecting the de-energization time, such as when breaker 1011 (or possibly breaker 1012) was opened, IED 1005 may determine the magnitude and polarity of the trapped charge on phase line 1010.

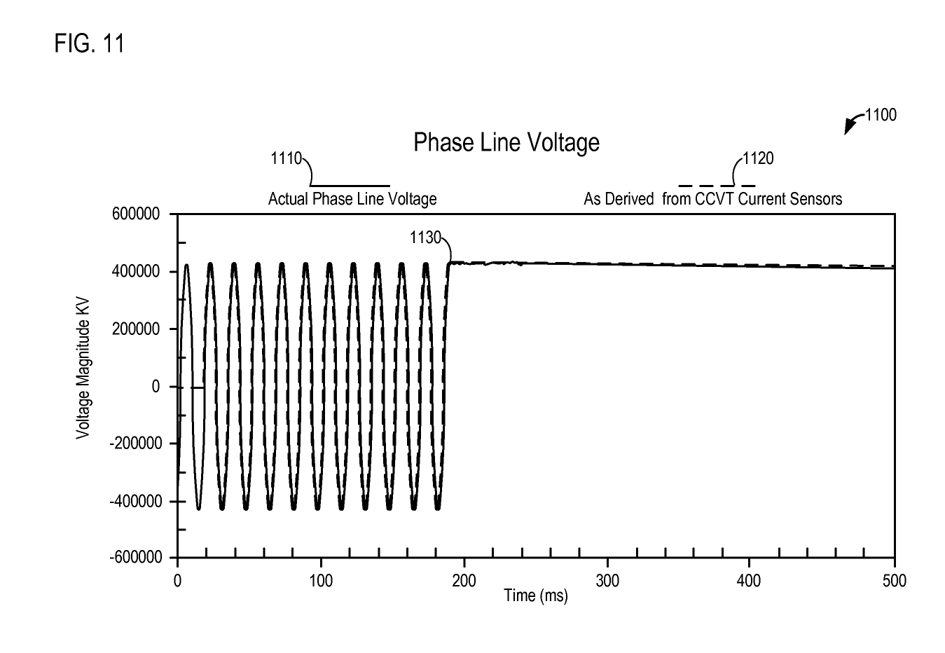

FIG. 11 illustrates an oscillographic comparison 1100 of an actual phase line voltage 1110 and a phase line voltage derived (derived phase line voltage 1120) using measurements taken from two current sensors. For example, derived phase line voltage 1120 may be determined using currents sensors 980 and 985 as illustrated in one of FIGS. 9A or 9B. As illustrated, actual phase line voltage 1110 and derived phase line voltage 1120 are nearly identical prior to a de-energizing event, at 1130. At de-energizing event 1130, the voltage on the primary winding of a CCVT would become zero due to the filtering effects of the primary capacitive assembly. Accordingly, a voltage derived from the output (secondary winding) of the CCVT would indicate that the phase line had a zero-voltage trapped charge following a de-energization event. In contrast, derived phase line voltage 1120, derived using measurements taken from two current sensors, accurately illustrates a non-zero-voltage trapped charge following the de-energizing event, at 1130.

By contrasting FIG. 6 with FIG. 11, it can be seen that while the output voltage of the CCVT cannot be used to accurately derive the trapped charge on a phase line (1110 in FIG. 6), using the current measured (or derived) through the primary and auxiliary capacitive assemblies of the CCVT can be used to accurately calculate the trapped charge on a phase line. Specifically, using the output voltage of the CCVT is unsuitable because of the poor transient response of CCVTs, due in part to the primary coupling capacitor acting as a DC filter. In contrast, and as illustrated in FIG. 11, the voltage calculated using the current measured (or derived) through the primary and auxiliary capacitive assemblies of the CCVT can be used to accurately find the trapped charge on a de-energized phase line.

The above description provides numerous specific details for a thorough understanding of the embodiments described herein. However, those of skill in the art will recognize that one or more of the specific details may be omitted, modified, and/or replaced by a similar process or system.

What is claimed:

1. A method for determining a trapped charge on a phase line, comprising:
determining a first current through a primary capacitive assembly, the primary capacitive assembly positioned between a phase line and a primary winding of a capacitance-coupled voltage transformer (CCVT);
determining a second current through an auxiliary capacitive assembly, the auxiliary capacitive assembly positioned between the primary capacitive assembly and a reference line;
determining a de-energization time corresponding to the instant the phase line is de-energized; and
calculating an instantaneous voltage on the phase line at the de-energization time using the first current, the second current, a known capacitance of the primary capacitive assembly, and a known capacitance of the auxiliary capacitive assembly.

2. The method of claim 1, wherein determining a de-energization time comprises determining a time at which the phase line is disconnected from an alternating current source.

3. The method of claim 1, wherein calculating an instantaneous voltage comprises:
integrating the first current through the primary capacitive assembly with respect to time to obtain a first integral;
dividing the first integral by the known capacitance of the primary capacitive assembly to obtain a first quotient;
integrating the second current through the auxiliary capacitive assembly with respect to time to obtain a second integral;
dividing the second integral by the known capacitance of the primary capacitive assembly to obtain a second quotient; and
adding the first quotient to the second quotient.

4. The method of claim 3, wherein calculating the instantaneous voltage on the phase line further comprises:
adjusting the known capacitance of the primary capacitive assembly to compensate for a measured temperature associated with the primary capacitive assembly; and
adjusting the known capacitance of the auxiliary capacitive assembly to compensate for a measured temperature associated with the auxiliary capacitive assembly.

5. The method of claim 1, wherein the phase line is a transmission line in a power distribution system.

6. The method of claim 1, wherein the reference line is a ground line.

7. The method of claim 1, wherein the reference line is a second phase line in a three-phase power system.

8. The method of claim 1, wherein the primary capacitive assembly comprises a first capacitive element and a second capacitive element connected in series.

9. The method of claim 1, wherein the primary capacitive assembly and the auxiliary capacitive assembly are part of a coupling-capacitor voltage divider, a tap of the coupling-capacitor voltage divider connected to the primary winding of the CCVT.

10. The method of claim 1, wherein the primary capacitive assembly and the auxiliary capacitive assembly are part of a capacitance-bushing voltage divider, a tap of the capacitance-bushing voltage divider connected to the primary winding of the CCVT.

11. The method of claim 1, wherein determining the second current through the auxiliary capacitive assembly comprises measuring the second current using an auxiliary current sensor positioned between the reference line and the auxiliary capacitive assembly; and
wherein determining the first current through the primary capacitive assembly comprises deriving the first current using the second current and a third current measured using a primary current sensor positioned between the primary winding of the CCVT and the reference line.

12. An intelligent electronic device (IED) configured to determine a trapped charge on a phase line comprising:
a processor; and
a memory in communication with the processor, the memory comprising instructions executable by the processor configured to cause the processor to:
receive a first current value from a first current sensor, the first current value corresponding to an electric current through a primary capacitive assembly positioned between a phase line and a primary winding of a capacitance-coupled voltage transformer (CCVT);
receive a second current value from a second current sensor, the second current value corresponding to an electric current through an auxiliary capacitive assembly, the auxiliary capacitive assembly positioned between the primary capacitive assembly and a reference line;
determine a de-energization time corresponding to the instant the phase line is de-energized; and
calculate an instantaneous voltage on the phase line at the de-energization time using the first current value, the second current value, a known capacitance of the primary capacitive assembly, and a known capacitance of the auxiliary capacitive assembly.

13. The IED of claim 12, wherein the instructions are further configured to cause the processor to determine a de-energization time by detecting a time at which the phase line is disconnected form an alternating current source.

14. The IED of claim 12, wherein, in order to calculate the instantaneous voltage, the instructions are further configured to cause the processor to:
integrate the first current value through the primary capacitive assembly with respect to time to obtain a first integral;
divide the first integral by the known capacitance of the primary capacitive assembly to obtain a first quotient;
integrate the second current value through the auxiliary capacitive assembly with respect to time to obtain a second integral;
divide the second integral by the known capacitance of the primary capacitive assembly to obtain a second quotient; and
adding the first quotient to the second quotient.

15. The IED of claim 12, wherein the instructions are further configured to cause the processor to:
adjust the known capacitance of the primary capacitive assembly to compensate for a measured temperature associated with the primary capacitive assembly; and
adjust the known capacitance of the auxiliary capacitive assembly to compensate for a measured temperature associated with the auxiliary capacitive assembly.

16. The IED of claim 12, wherein the phase line is a transmission line in a power distribution system.

17. The IED of claim 12, wherein the reference line comprises a ground line.

18. The IED of claim 12, wherein the reference line comprises a second phase line in a three-phase power system.

19. The IED of claim 12, wherein the primary capacitive assembly comprises a first capacitive element and a second capacitive element connected in series.

20. The IED of claim 12, wherein the primary capacitive assembly and the auxiliary capacitive assembly are part of a coupling-capacitor voltage divider, a tap of the coupling-capacitor voltage divider connected to the primary winding of the CCVT.

21. The IED of claim 12, wherein the primary capacitive assembly and the auxiliary capacitive assembly are part of a capacitance-bushing voltage divider, a tap of the capacitance-bushing voltage divider connected to the primary winding of the CCVT.

22. The IED of claim 12, wherein the second current sensor is positioned between the reference line and the auxiliary capacitive assembly, so as to directly measure the electric current through the auxiliary capacitive assembly; and
wherein the first current sensor is positioned between the primary winding of the CCVT and the reference line, such that the IED may derive the electric current through the primary capacitive assembly using the first current value and the second current value.

23. A method for determining a trapped charge on a phase line, comprising:
an intelligent electronic device (IED) receiving a first current value from a first current sensor, the first current value corresponding to an electric current through a primary capacitive assembly, the primary capacitive assembly positioned between a phase line and a primary winding of a capacitance-coupled voltage transformer (CCVT);
the IED receiving a second current value from a second current sensor, the second current value corresponding to an electric current through an auxiliary capacitive assembly, the auxiliary capacitive assembly positioned between the primary capacitive assembly and a reference line;
the IED determining a de-energization time corresponding to the instant the phase line is de-energized; and
The IED calculating an instantaneous voltage on the phase line at the de-energization time using the first current value, the second current value, a known capacitance of the primary capacitive assembly, and a known capacitance of the auxiliary capacitive assembly.

24. The method of claim 23, wherein the IED calculating the instantaneous voltage on the phase line further comprises:
the IED adjusting the known capacitance of the primary capacitive assembly to compensate for a measured temperature associated with the primary capacitive assembly; and
the IED adjusting the known capacitance of the auxiliary capacitive assembly to compensate for a measured temperature associated with the auxiliary capacitive assembly.

25. The method of claim 23, wherein calculating an instantaneous voltage comprises the IED:
integrating the first current through the primary capacitive assembly with respect to time to obtain a first integral;
dividing the first integral by the capacitance of the primary capacitive assembly to obtain a first quotient;
integrating the second current through the auxiliary capacitive assembly with respect to time to obtain a second integral;
dividing the second integral by the capacitance of the primary capacitive assembly to obtain a second quotient; and
adding the first quotient to the second quotient.
